(19) United States
(12) Patent Application Publication
(10) Pub. No.: US 2006/0181358 A1
(43) Pub. Date: Aug. 17, 2006

(54) Semiconductor device generating accurate oscillating signal based on RC oscillation

(75) Inventors: Kouji Kitagawa, Kawasaki (JP); Minoru Usui, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/151,313

(22) Filed: Jun. 14, 2005

(30) Foreign Application Priority Data
Feb. 17, 2005 (JP) 2005-040975

(51) Int. Cl. H03B 5/20

(52) U.S. Cl. 331/135

(57) ABSTRACT

A semiconductor device includes a RC oscillator configured to produce at an output thereof a first oscillating signal oscillating at a first cycle, a measurement circuit coupled to the output of the RC oscillator to produce at an output thereof a measurement obtained by measuring a length of the first cycle of the first oscillating signal by using as a reference a second oscillating signal having a second cycle, and a correction circuit coupled to the output of the measurement circuit and to the output of the RC oscillator to divide a frequency of the first oscillating signal by a number responsive to the measurement.

### CROSS-REFERENCE TO RELATED APPLICATIONS

The present application is based upon and claims the benefit of priority from the prior Japanese Patent Application No. 2005-040975 filed on Feb. 17, 2005, with the Japanese Patent Office, the entire contents of which are incorporated herein by reference.

### BACKGROUND OF THE INVENTION

1. Field of the Invention

The present invention generally relates to semiconductor devices, and particularly relates to a semiconductor device provided with a built-in RC oscillator.

2. Description of the Related Art

Some types of semiconductor devices are provided with a built-in RC oscillating circuit. A microcomputer having a built-in RC oscillating circuit, for example, is an example of a microcomputer that is provided with the function to prevent malfunction. When a failure such as the decoupling of an external oscillator occurs, a clock monitoring circuit for monitoring the clock inside the microcomputer switches the operating clock to the oscillating signal of the built-in RC oscillating circuit. With this provision, the microcomputer can continue its operation.

In actual semiconductor devices, there is manufacturing variation in the thickness of inter-layer films, the thickness of interconnect lines, the width of interconnect lines, etc. This causes the resistance of R and the capacitance of C inside the RC oscillating circuit to vary. For example, the conditions of manufacturing processes may slightly vary depending on the time of manufacture. This gives rise to a problem in that the oscillating frequency of a RC oscillating circuit varies depending on the time the semiconductor device is manufactured. In such semiconductor devices, the use of the oscillating frequency of the built-in RC oscillating circuit as a clock signal results in variation in the operating speed, which makes it difficult to guarantee correct operations. Further, application of a RC oscillating circuit having such low precision is quite limited.

In order to obviate the problems as described above, the oscillating frequency of the built-in RC oscillating circuit may be measured after the manufacturing of a semiconductor device, and the value of resistance or the like in the RC oscillating circuit may be corrected based on the obtained measurements so as to attain a desired frequency. Specifically, a fuse circuit may be provided. A choice of cutting the fuse or leaving the fuse intact serves to adjust the size of resistance coupled to the RC oscillating circuit.

As another method to obviate the problems, the oscillating frequency of the built-in RC oscillating circuit may be measured after the manufacturing of a semiconductor device, and the obtained measurements may be stored in a built-in nonvolatile ROM. At the time of system software development, the variation can be absorbed by a software means utilizing the recorded frequency measurements. This can reduce influence resulting from the variation in the oscillating frequency of a RC oscillating circuit.

In the correction method based on the use of a fuse circuit as described above, the presence of the fuse circuit adds to circuit size. Also, the process step of frequency measurement and the process step of fuse handling are required as additional process steps, resulting in an increase in the costs of manufacturing the semiconductor device. In the method based on the use of a nonvolatile ROM, also, there are additional process steps including the measurement of the frequency and the manufacturing and testing of the nonvolatile ROM, which results in an increase in the costs of manufacturing the semiconductor device.

The oscillating frequency of a RC oscillating circuit also varies in response to a change in temperature or the like. The methods described above have a drawback in that they cannot cope with the fluctuation factors relating to the ongoing operation of the semiconductor device. As a method that obviates this drawback, the invention disclosed in Patent Document 1 measures an interval of communications made by an external unit (e.g., a main microcomputer) by use of an operating clock supplied from a RC oscillating circuit provided in a local unit (sub-microcomputer). An error of the local clock is detected based on the obtained measurements, and is then used to correct the local clock. This makes it possible to provide a microcomputer capable of reliable communication while relying on an inexpensive RC oscillating circuit.

The method described in Patent Document 1, however, requires a specific signal to be supplied from an external source to the semiconductor device (sub-microcomputer) provided with a built-in RC oscillating circuit. This means that the semiconductor device having a built-in RC oscillating circuit needs to have an apparatus to communicate with, and that the semiconductor device having a built-in RC oscillating circuit needs to have a communication function.

[Patent Document 1] Japanese Patent Application Publication No. 10-247121

Accordingly, there is a need for a semiconductor device that can cope with the fluctuation factors of oscillating frequency relating to the time of operation of the semiconductor device, and that can correct the oscillating frequency of the RC oscillating circuit without requiring a special communication function or an apparatus to communicate with.

### SUMMARY OF THE INVENTION

It is a general object of the present invention to provide a semiconductor device that substantially obviates one or more problems caused by the limitations and disadvantages of the related art.

Features and advantages of the present invention will be presented in the description which follows, and in part will become apparent from the description and the accompanying drawings, or may be learned by practice of the invention according to the teachings provided in the description. Objects as well as other features and advantages of the present invention will be realized and attained by a semiconductor device particularly pointed out in the specification in such full, clear, concise, and exact terms as to enable a person having ordinary skill in the art to practice the invention.

To achieve these and other advantages in accordance with the purpose of the invention, the invention provides a semiconductor device which includes a RC oscillator configured to produce at an output thereof a first oscillating signal oscillating at a first cycle, a measurement circuit coupled to the output of the RC oscillator to produce at an output thereof a measurement obtained by measuring a length of the first cycle of the first oscillating signal by using as a reference a second oscillating signal having a second cycle, and a correction circuit coupled to the output of the measurement circuit and to the output of the RC oscillator to divide a frequency of the first oscillating signal by a number responsive to the measurement.

According to at least one embodiment of the present invention, the first cycle of the oscillating signal of the RC oscillating circuit is measured based on the second cycle of the oscillating signal of the crystal oscillator, and a number indicative of how many first cycles are equal in length to a desired cycle is computed based on the obtained measurements. Based on the computed number, a signal having the desired cycle is generated by dividing the frequency of the oscillating signal of the RC oscillating circuit. With this provision, the oscillating signal of the RC oscillating circuit having variation and fluctuation is corrected by using as a reference the oscillating signal of the highly precise, stable crystal oscillator. This achieves a desired cycle with high precision while using the oscillating signal of the RC oscillating circuit.

### BRIEF DESCRIPTION OF THE DRAWINGS

Other objects and further features of the present invention will be apparent from the following detailed description when read in conjunction with the accompanying drawings, in which:

FIG. 1 is a drawing showing an example of the configuration of a semiconductor device according to the present invention;

FIGS. 2A and 2B are signal timing charts for explaining the operation of the circuit shown in FIG. 1;

FIG. 3 is a drawing showing an example of the configuration of the semiconductor device according to the present invention in which hardware-based correction is performed; and

FIGS. 4A and 4B are signal timing charts for explaining the operation of the circuit shown in FIG. 3.

### DESCRIPTION OF THE PREFERRED EMBODIMENTS

In the following, embodiments of the present invention will be described with reference to the accompanying drawings.

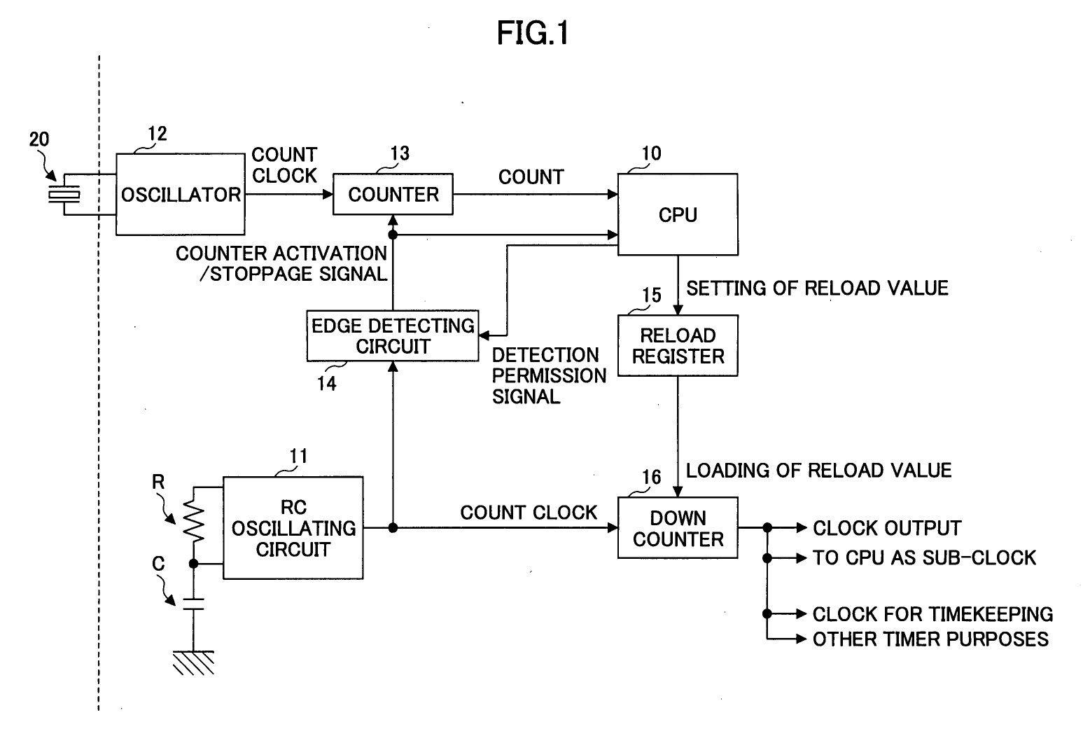

FIG. 1 is a drawing showing an example of the configuration of a semiconductor device according to the present invention.

The semiconductor device of FIG. 1 includes a CPU 10, a RC oscillating circuit 11, a crystal oscillator 12, a counter 13, an edge detecting circuit 14, a reload register 15, and a down counter 16. The RC oscillating circuit 11 oscillates at the oscillating frequency responsive to resistance R and capacitance C provided in the semiconductor device. As previously described, semiconductor devices have manufacturing variation in the thickness of inter-layer films, the thickness of interconnect lines, the width of interconnect lines, etc, which causes the resistance R and capacitance C of the RC oscillating circuit to vary. Because of this, the oscillating frequency of the RC oscillating circuit may vary depending on the time the semiconductor device is manufactured, for example. The oscillating frequency also varies in response to a temperature change or the like.

The crystal oscillator 12 oscillates at highly precise oscillating frequency by utilizing the resonance effect of a crystal resonator 20 provided as an external part. The crystal oscillator 12 is generally more than 1000 times as accurate as a RC oscillating circuit, and its oscillating frequency has little temperature dependency. The example shown in FIG. 1 uses the crystal resonator and the crystal oscillator 12. If precision is not of prime importance, however, a ceramic oscillator or the like may be used depending on the type of application.

In the present invention, the highly precise oscillating frequency of the crystal oscillator 12 is used to measure the low-precision oscillating frequency of the RC oscillating circuit 11, and, then, the oscillating frequency of the RC oscillating circuit 11 is corrected based on the obtained measurements. The CPU 10 serves as a control circuit for controlling the measurement of the oscillating frequency and the correction operation. It is assumed that the high-precision oscillating frequency of the crystal oscillator 12 has higher frequency than the low-precision oscillating frequency of the RC oscillating circuit 11.

The CPU 10 supplies a detection permission signal to the edge detecting circuit 14. In response to this detection permission signal, the measurement of the low-precision oscillating frequency of the RC oscillating circuit 11 by use of the high-precision oscillating frequency of the crystal oscillator 12 is started. After receiving the detection permission signal, the edge detecting circuit 14 detects a rising edge of the oscillating signal of the RC oscillating circuit 11, and generates a counter activation signal in response to the detection of the rising edge. The counter activation signal is supplied to the counter 13. Upon receiving the counter activation signal from the edge detecting circuit 14, the counter 13 starts counting the pulses of the oscillating signal supplied from the crystal oscillator 12.

Thereafter, the edge detecting circuit 14 detects a rising edge of the oscillating signal of the RC oscillating circuit 11, and generates a counter stoppage signal in response to the detection of this rising edge. The counter stoppage signal is supplied to the counter 13. The counter activation signal and the counter stoppage signal may be represented by a single signal that has an asserted state and a negated state corresponding to a start instruction and a stop instruction, respectively. Upon receiving the counter stoppage signal from the edge detecting circuit 14, the counter 13 stops counting the pulses of the oscillating signal supplied from the crystal oscillator 12.

The count stoppage signal generated by the edge detecting circuit 14 is also supplied to the CPU 10. In response to the count stoppage signal, the CPU 10 reads the count that is output from the counter 13. The count indicates the number of pulses of the oscillating signal of the crystal oscillator 12 that are counted during a period from a given rising edge to a next rising edge of the oscillating signal of the RC oscillating circuit 11, i.e., during a one-cycle period of the oscillating signal of the RC oscillating circuit 11. Accordingly, this count indicates how many times the cycle of the oscillating signal of the RC oscillating circuit 11 is longer than the cycle of the oscillating signal of the crystal oscillator 12.

Based on the read count, the CPU 10 computes the number of cycles of the oscillating signal of the RC oscillating circuit 11 that is required to measure a desired period, and stores the computed number in the reload register 15. The down counter 16 reads the number stored in the reload register 15 as an initial value, and starts counting down by using the oscillating signal of the RC oscillating circuit 11 as a clock. When the count reaches zero, the down counter 16 inverts its output (i.e., changes the output from HIGH to LOW or from LOW to HIGH). Further, the down counter 16 reads the number stored in the reload register 15 as an initial value again when the count reaches zero, and starts counting down by using the oscillating signal of the RC oscillating circuit 11 as a clock. When the count reaches zero, the down counter 16 inverts its output (i.e., changes the output from HIGH to LOW or from LOW to HIGH).

In this manner, the down counter 16 performs a toggle operation. As a result, the output of the down counter 16 alternates between HIGH and LOW at a cycle that is equal to the oscillating cycle of the RC oscillating circuit 11 multiplied by the number stored in the reload register 15. That is, the oscillating signal of the RC oscillating circuit 11 is frequency-divided by the number stored in the reload register 15. As a result, a clock signal having the above-noted desired cycle is obtained from the oscillating signal of the RC oscillating circuit 11.

The clock signal obtained in this manner may be supplied to an exterior as a clock signal, may be supplied to a CPU as a sub-clock signal, may be used as a timekeeping-purpose clock, or may be used for other timer operations.

Here, the oscillating frequency of the RC oscillating circuit 11 is denoted as tRC, the oscillating frequency of the crystal oscillator 12 as tOSC, the desired cycle as T, and the above-described count of the counter 13 as α. In this case, a number β stored in the reload register 15 is represented as:
β=T/tRC=T/(α×tOSC). (1)
The CPU 10 computes this β based on the count α and the oscillating frequency tOSC of the crystal oscillator 12. tOSC may be 250 ns, and the count α may be 41, for example. In order to achieve a desired cycle of 100 ms, the number stored in the reload register 15 needs to be 9756 as follows.

$$\begin{matrix}β = 100 \times {10}^{- 3} / ( 41 \times 250 \times {10}^{- 9} ) \\ = 9756\end{matrix}$$

With this, the output of the down counter 16 toggles after the passage of time corresponding to 9756 cycles of the oscillating signal of the RC oscillating circuit 11. That is, the output of the down counter 16 changes from HIGH to LOW and from LOW to HIGH at a desired cycle of 100 ms.

In the embodiment of the present invention as described above, the first cycle of the oscillating signal of the RC oscillating circuit 11 is measured based on the second cycle of the oscillating signal of the crystal oscillator 12, and a number indicative of how many first cycles are equal in length to a desired cycle is computed based on the obtained measurements. Based on the computed number, a signal having the desired cycle is generated by using the oscillating signal of the RC oscillating circuit 11. With this provision, the oscillating signal of the RC oscillating circuit 11 having variation and fluctuation is corrected by using as a reference the oscillating signal of the highly precise, stable crystal oscillator 12. This achieves a desired cycle with high precision while using the oscillating signal of the RC oscillating circuit 11.

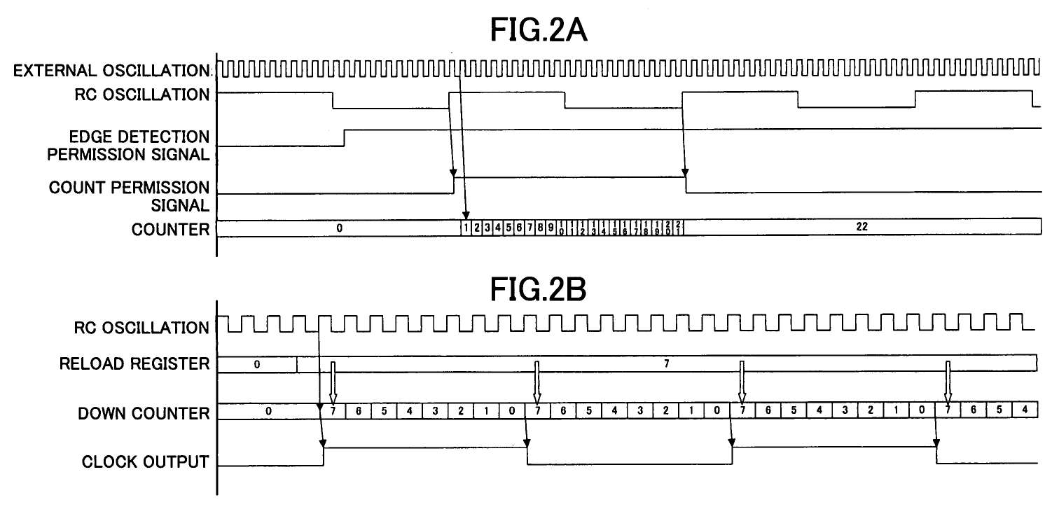

FIGS. 2A and 2B are signal timing charts for explaining the operation of the circuit shown in FIG. 1. FIG. 2A illustrates the measurement of the cycle of the oscillating signal of the RC oscillating circuit 11, and FIG. 2B illustrates the timekeeping of a desired cycle by using the oscillating signal of the RC oscillating circuit 11.

As shown in FIG. 2A, the RC oscillation of the RC oscillating circuit 11 has a longer cycle than the external oscillation of the crystal oscillator 12 (the external crystal resonator 20). When the edge detection permission signal from the CPU 10 is asserted to HIGH, the edge detecting circuit 14 asserts the count permission signal (the counter activation/stoppage signal shown in FIG. 1) to HIGH in response to a rising edge of the RC oscillation immediately following the assertion of the edge detection permission signal. In response, the counter 13 starts counting the pulses of the external oscillation. In FIG. 2A, the count starts from zero, and increases by one at a time in synchronization with the external oscillation.

In response to a next rising edge of the RC oscillation, the edge detecting circuit 14 negates the count permission signal (the counter activation/stoppage signal shown in FIG. 1) to LOW. In response, the counter 13 stops counting the pulses of the external oscillation. In FIG. 2A, the count is suspended at 22.

FIG. 2B illustrates a case in which the desired cycle is equal in length to 176 cycles of the external oscillation, i.e., T=176 tOSC. The CPU 10 computes the value of the equation (1) based on the desired cycle (T=176 tOSC) and a count of 22 (α=22), thereby obtaining β=8. Based on this β, the CPU 10 stores “7” in the reload register 15.

The down counter 16 uses the value “7” stored in the reload register 15 as an initial value, and decreases its count one by one in synchronization with the pulses of the RC oscillation. When the count reaches zero, the down counter 16 inverts its output (i.e., the clock output). As a result, the clock output repeats an inverting operation at the desired cycle (T=176 tOSC).

In the example shown in FIG. 2B, “7” in stead of “8” is stored in the reload register 15. This is because the down counter 16 is configured to invert its output at the cycle next following the cycle at which the count reaches zero. If the down counter 16 is configured to invert its output at the instant the count reaches zero, the value “8” of β, as it is, should be stored in the reload register 15. This is simply a matter of design choice.

In the configuration shown in FIG. 1, the correction-purpose value stored in the reload register 15 is obtained through the computation by the CPU 10. Rather than computing the correction value through software-based control operation in this manner, a hardware-based control operation may be performed to store the correction value in the reload register 15.

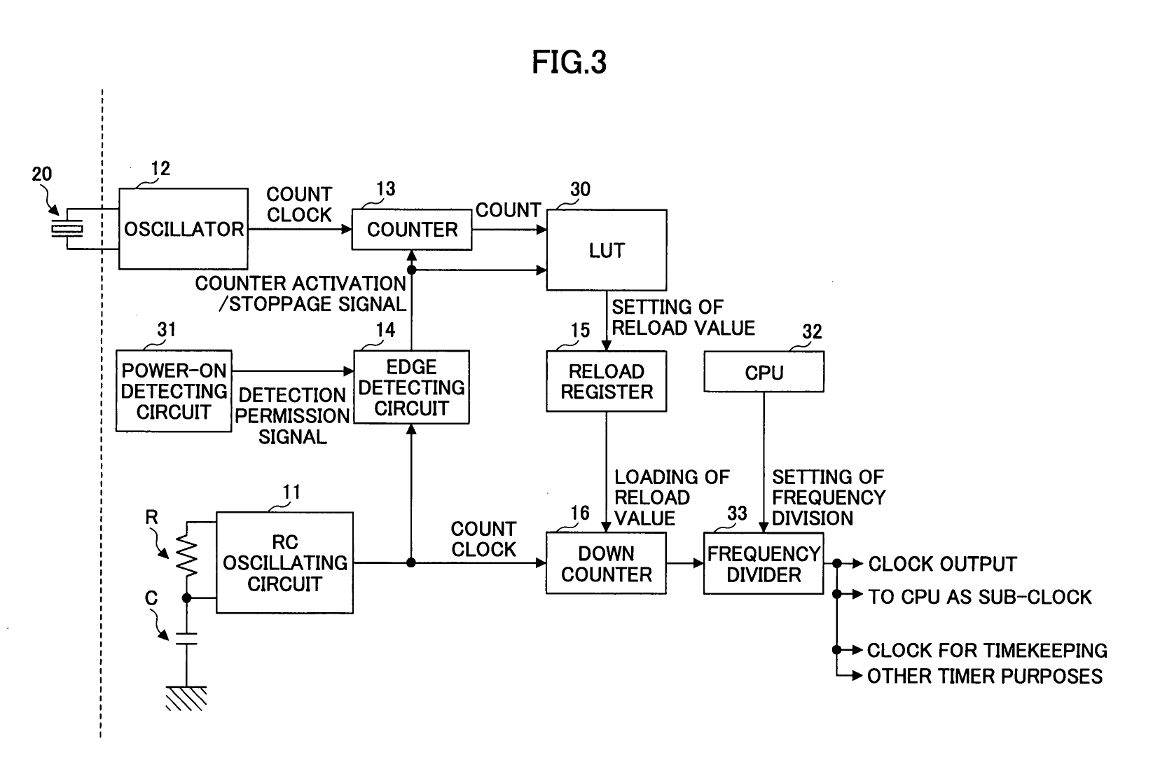

FIG. 3 is a drawing showing an example of the configuration of the semiconductor device according to the present invention in which hardware-based correction is performed. In FIG. 3, the same elements as those of FIG. 1 are referred to by the same numerals.

The semiconductor device shown in FIG. 3 includes a LUT (look-up table) 30, a power-on detecting circuit 31, a CPU 32, and a frequency divider 33 in addition to the RC oscillating circuit 11, the crystal oscillator 12, the counter 13, the edge detecting circuit 14, the reload register 15, and the down counter 16 shown in FIG. 1.

As the semiconductor device is powered on, the power-on detecting circuit 31 detects the power-on to assert the detection permission signal. The detection permission signal is designed such that its assertion starts after waiting for a time period required for the oscillation of the crystal oscillator 12 to stabilize after the detection of the power-on.

In response to the detection permission signal, the measurement starts to take the measurement of the low-precision oscillating frequency of the RC oscillating circuit 11 by use of the high-precision oscillating frequency of the crystal oscillator 12. Upon receiving the detection permission signal, the edge detecting circuit 14 detects a rising edge of the oscillating signal of the RC oscillating circuit 11, and generates the counter activation signal in response to the detection of the rising edge. The counter activation signal is supplied to the counter 13. Upon receiving the counter activation signal from the edge detecting circuit 14, the counter 13 starts counting the pulses of the oscillating signal supplied from the crystal oscillator 12.

Thereafter, the edge detecting circuit 14 detects a rising edge of the oscillating signal of the RC oscillating circuit 11, and generates the counter stoppage signal in response to the detection of this rising edge. The counter stoppage signal is supplied to the counter 13. The counter activation signal and the counter stoppage signal may be represented by a single signal that has an asserted state and a negated state corresponding to a start instruction and a stop instruction, respectively. Upon receiving the counter stoppage signal from the edge detecting circuit 14, the counter 13 stops counting the pulses of the oscillating signal supplied from the crystal oscillator 12.

The count stoppage signal generated by the edge detecting circuit 14 is also supplied to the LUT 30. In response to the count stoppage signal, the LUT 30 supplies to the reload register 15 the value of a table entry corresponding to the count supplied from the counter 13. The LUT 30 is a memory that stores the values β of the equation (1) as data in table format, and that provides an output β corresponding to the supplied input.

If the desired cycle T and the cycle tOSC of the crystal oscillator 12 are fixed, for example, the value that is to be supplied to the reload register 15 is a function of the count α alone. In this case, therefore, the LUT 30 stores a table of a one-dimensional array having the count α as its variable, and takes out a value corresponding to the supplied count α for provision as an output. Further, provision may be made such that the desired cycle is also selectable. In such a case, the LUT 30 stores a two-dimensional array having the desired cycle T and the count α as its variables, with a signal indicative of the desired cycle being input into the LUT 30, and a corresponding function value being read out. By the same token, provision may be made such that the cycle tOSC is also selectable.

The down counter 16 reads the number stored in the reload register 15 as an initial value, and starts counting down by using the oscillating signal of the RC oscillating circuit 11 as a clock. When the count reaches zero, the down counter 16 inverts its output. Further, the down counter 16 reads the number stored in the reload register 15 as an initial value again when the count reaches zero, and starts counting down by using the oscillating signal of the RC oscillating circuit 11 as a clock. When the count reaches zero, the down counter 16 inverts its output.

In this manner, the down counter 16 performs a toggle operation. As a result, the output of the down counter 16 inverts at a cycle that is equal to the oscillating cycle of the RC oscillating circuit 11 multiplied by the number stored in the reload register 15. That is, the oscillating signal of the RC oscillating circuit 11 is frequency-divided by the number stored in the reload register 15. As a result, a clock signal having the desired cycle is obtained from the oscillating signal of the RC oscillating circuit 11.

The clock signal obtained in this manner is supplied to the frequency divider 33. The frequency divider 33 divides the frequency of the signal supplied from the down counter 16 according to the frequency division ratio that is set by the CPU 32. A signal obtained by the frequency division may be supplied to an exterior as a clock signal, may be supplied to a CPU as a sub-clock signal, may be used as a timekeeping-purpose clock, or may be used for other timer operations (e.g., a watchdog timer operation or the like). It should be noted that the frequency divider 33 is not an element essential for the correction of the oscillating signal of the RC oscillating circuit 11. The frequency divider 33 is provided to demonstrate that a frequency division ratio is freely set to generate a signal having a desired cycle, without being limited to the cycle generated by the correction circuit (i.e., the reload register 15 and the down counter 16).

In the embodiment of the present invention described above, when the semiconductor device is powered on, the first cycle of the oscillating signal of the RC oscillating circuit 11 is measured based on the second cycle of the oscillating signal of the crystal oscillator 12, and a number indicative of how many first cycles are equal in length to a desired cycle is retrieved from the LUT. Based on the retrieved number, a signal having the desired cycle is generated by using the oscillating signal of the RC oscillating circuit 11. With this provision, the oscillating signal of the RC oscillating circuit 11 having variation and fluctuation is corrected by using as a reference the oscillating signal of the highly precise, stable crystal oscillator 12. This achieves a desired cycle with high precision while using the oscillating signal of the RC oscillating circuit 11.

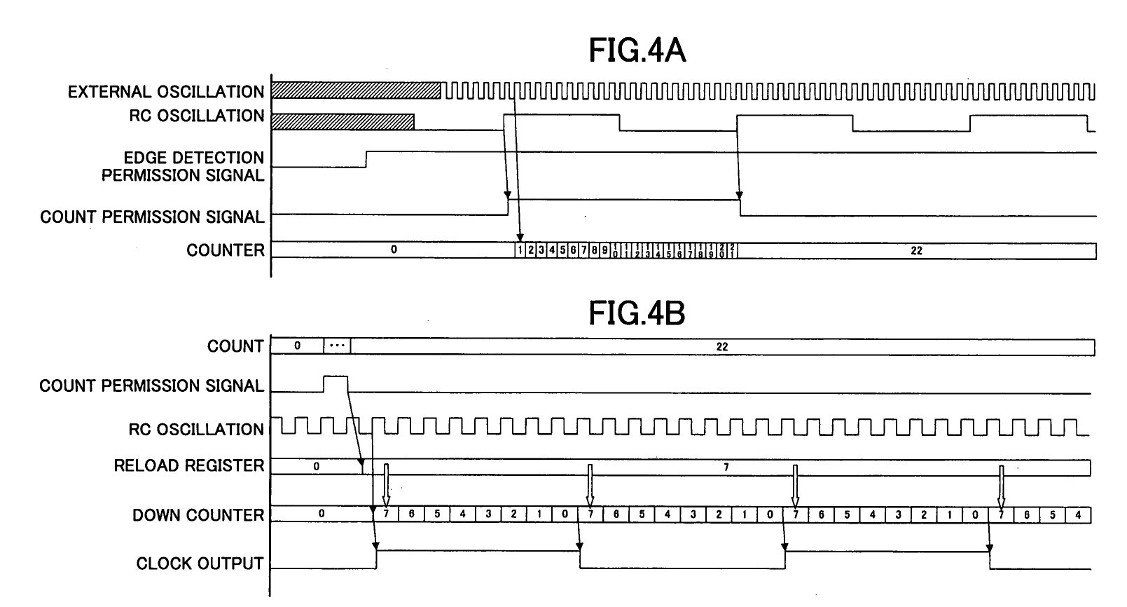

FIGS. 4A and 4B are signal timing charts for explaining the operation of the circuit shown in FIG. 3. FIG. 3A illustrates the measurement of the cycle of the oscillating signal of the RC oscillating circuit 11, and FIG. 2B illustrates the timekeeping of a desired cycle by using the oscillating signal of the RC oscillating circuit 11.

In FIG. 4A, an external oscillation by the crystal oscillator 12 (external crystal resonator 20) and a RC oscillation by the RC oscillating circuit 11 are not illustrated toward the left-hand-side end of the drawing. This corresponds to the period immediately following the power-on, during which the oscillating frequencies of the oscillators are not stable.

When the edge detection permission signal from the power-on detecting circuit 31 is asserted to HIGH, the edge detecting circuit 14 asserts the count permission signal (the counter activation/stoppage signal shown in FIG. 1) to HIGH in response to a rising edge of the RC oscillation immediately following the assertion of the edge detection permission signal. In response, the counter 13 starts counting the pulses of the external oscillation. In FIG. 4A, the count starts from zero, and increases by one at a time in synchronization with the external oscillation.

In response to a next rising edge of the RC oscillation, the edge detecting circuit 14 negates the count permission signal (the counter activation/stoppage signal shown in FIG. 1) to LOW. In response, the counter 13 stops counting the pulses of the external oscillation. In FIG. 4A, the count is suspended at 22.

FIG. 4B illustrates a case in which the desired cycle is equal in length to 176 cycles of the external oscillation, i.e., T=176 tOSC. The LUT 30 stores the values of β corresponding to respective counts in table format with respect to the case in which the desired cycle T is 176 tOSC. The LUT 30 selects β=7 from the table entries in response to a count of 22 (α=22), and provides β as an output. This is performed by outputting a table entry corresponding to the supplied count (α=22) in response to a change of the count permission signal to the negated state (LOW). This β=7 output from the LUT 30 is stored in the reload register 15.

The down counter 16 uses the value “7” stored in the reload register 15 as an initial value, and decreases its count one by one in synchronization with the pulses of the RC oscillation. When the count reaches zero, the down counter 16 inverts its output (i.e., the clock output). As a result, the clock output repeats an inverting operation at the desired cycle (T=176 tOSC).

Further, the present invention is not limited to these embodiments, but various variations and modifications may be made without departing from the scope of the present invention.

What is claimed is:

1. A semiconductor device, comprising:
a RC oscillator configured to produce at an output thereof a first oscillating signal oscillating at a first cycle;
a measurement circuit coupled to the output of said RC oscillator to produce at an output thereof a measurement obtained by measuring a length of the first cycle of the first oscillating signal by using as a reference a second oscillating signal having a second cycle; and
a correction circuit coupled to the output of said measurement circuit and to the output of said RC oscillator to divide a frequency of the first oscillating signal by a number responsive to the measurement.

2. The semiconductor device as claimed in claim 1, further comprising an oscillator configured to generate the second oscillating signal.

3. The semiconductor device as claimed in claim 2, wherein said oscillator configured to generate the second oscillating signal is a crystal oscillator.

4. The semiconductor device as claimed in claim 1, wherein said measurement circuit includes a counter configured to count a number of second cycles included in a period equal to the first cycle of the first oscillating signal.

5. The semiconductor device as claimed in claim 4, wherein said measurement circuit further includes an edge detecting circuit coupled to the output of said RC oscillator to detect a predetermined edge of the first oscillating signal, wherein said counter is configured to start counting pulses of the second oscillating signal in response to the detection of an edge by the edge detecting circuit and to stop counting the pulses of the second oscillating signal in response to the detection of another edge by the edge detection circuit.

6. The semiconductor device as claimed in claim 1, wherein said measurement circuit takes the measurement in response to power-on of the semiconductor device.

7. The semiconductor device as claimed in claim 1, wherein said correction circuit includes:
a circuit configured to produce a ratio of a desired cycle to the first cycle in response to the measurement; and
a counter configured to divides the frequency of the first oscillating signal in response to the ratio.

8. The semiconductor device as claimed in claim 7, wherein said circuit configured to produce the ratio is a CPU operable to compute the ratio of the desired cycle to the first cycle in response to the measurement.

9. The semiconductor device as claimed in claim 7, wherein said circuit configured to produce the ratio is a memory operable to store the ratio of the desired cycle to the first cycle separately for each said measurement.

10. A method of correcting an oscillating frequency, comprising the steps of:
generating a first oscillating signal oscillating at a first cycle by a RC oscillator;
generating a second oscillating signal oscillating at a second cycle by a crystal oscillator;
counting a number of second cycles included in the first cycle; and
dividing a frequency of the first oscillating signal in response to a number responsive to the counted number of the second cycles.
